(19) United States
(12) Patent Application Publication
(10) Pub. No.: US 2004/0137943 A1
(43) Pub. Date: Jul. 15, 2004

(54) FM receiving module for PDA/notebook

(76) Inventor: Fuh-Shan Tseng, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/339,388

(22) Filed: Jan. 10, 2003

(51) Int. Cl. H04B 1/06; H05K 11/00; H04M 1/00; H04B 1/38

(52) U.S. Cl. 455/556.2; 455/344

(57) ABSTRACT

A FM receiving module for a PDA/notebook is provided. The FM receiving module can receive a FM frequency and include an audio jack. The present invention is connected to a PDA or a notebook through a CF or SD interface and can control the FM receiving module through a control program. The control program can control the method of searching a FM frequency or memorizing a FM frequency and also can control the audio signal which will be produced from the audio jack.

### BACKGROUND OF THE INVENTION

1. Field of the Invention

The present invention relates to a FM receiving module for a PDA/notebook, and more particular to a FM receiving module through a control program to control a searching and a memorizing methods of a FM frequency and then send an audio signal out.

2. Description of the Prior Art

Generally, the notebook or PDA owns few expended supports for the audio. When it is needed to play the music via the notebook or PDA, the user has to download or store a desired audio file and then utilizes a built-in or the other players to play the music or sound. Furthermore, the notebook can also read an audio file stored in a CD disc for playing the music or sound. However, in the methods described above, the user needs to own the desired file firstly and then to play by a player for producing the sound. Otherwise, when the user wants to listen to the radio, it must to additionally prepare a radio or other machine which can receive the broadcast for achieving the purpose. Consequently, it is a rain improving challenge now to increase a greater efficiency of the PDA/notebook.

Thus it can bee seen, the prior art described above still has some defects, is not a good design, however, and is urgently to be improved.

Because of the technical defects of described above, the applicant keeps on carving unflaggingly to develop the FM receiving module for the PDA/notebook through wholehearted experience and research.

### SUMMARY OF THE INVENTION

An object of the present invention is to provide a FM receiving module for a PDA/notebook to increase other functions of the notebook or PDA and also develop a greater efficiency of the notebook or PDA.

Another object of the present invention is to provide a FM receiving module for a PDA/notebook which can make a connection to a PDA or a notebook through a CF or SD interface thereof and also can, through a control program, control a searching or memorizing of a FM frequency in the FM receiving module and a transmission of an audio signal.

The FM receiving module for the PDA/notebook for achieving the purposes described above includes a CF or SD interface circuit, a control chip, a FM receiver, an audio controller, an audio amplification circuit, and an extendable audio jack and can be controlled through cooperating with a control program. The present invention utilizes the CF or SD interface to make a connection to the PDA/notebook and also utilizes the control program to control the FM receiving module. The control program controls a searching or a memorizing method of a FM frequency and also controls an audio signal sent from an audio jack according to the present invention.

### BRIEF DESCRIPTION OF THE DRAWINGS

The drawings disclose an illustrative embodiment of the present invention which serves to exemplify the various advantages and objects hereof, and are as follows:

FIG. 1 is a block diagram of the framework of a FM receiving module for a PDA/notebook according to the present invention;

FIG. 2 is a block diagram of the software of the FM receiving module for a PDA/notebook; and

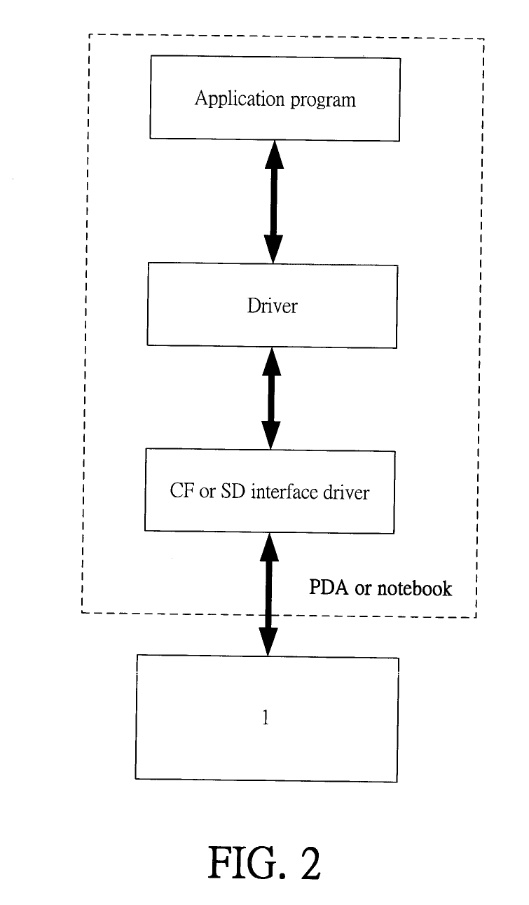

FIG. 3 is a flow chart of the software control of the FM receiving module for a PDA/notebook.

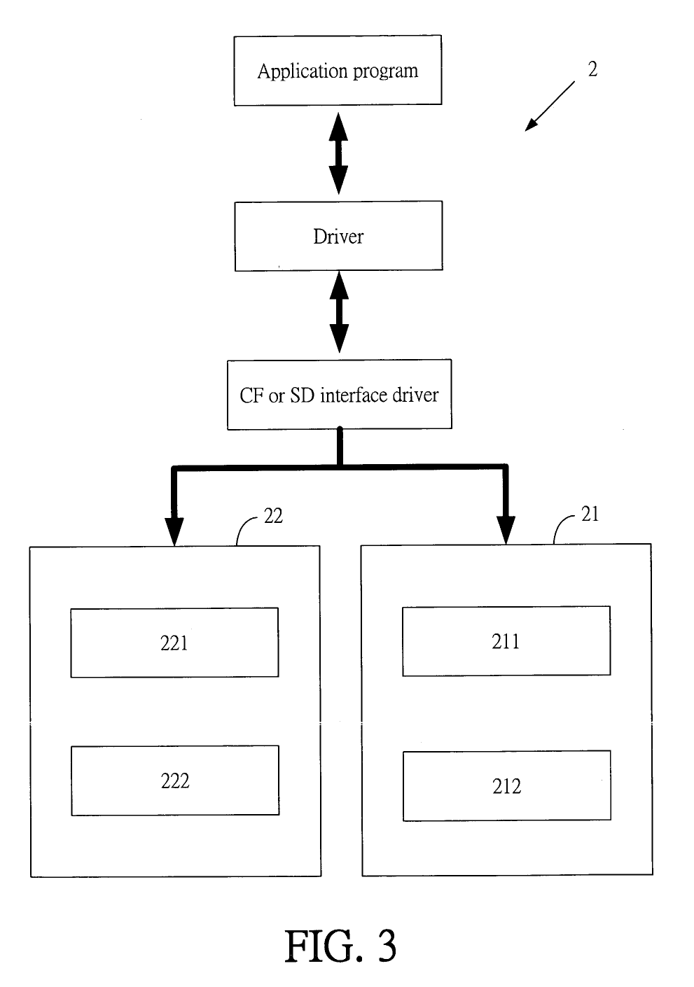

### DETAILED DESCRIPTION OF THE PREFERRED EMBODIMENT

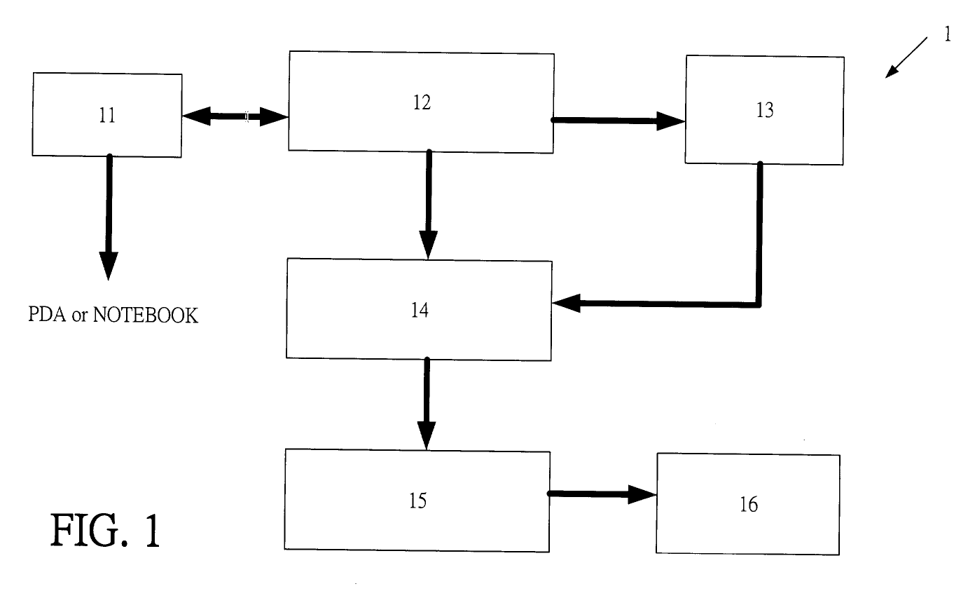

Please refer to FIGS. 1˜3. The present invention provides a FM receiving module 1 for a PDA/notebook. The FM receiving module 1 includes a CF or SD interface circuit 11, a control chip 12, a FM receiver 13, an audio controller 14, an audio amplification circuit 15, and an extendable audio jack 16 and can be controlled through cooperating with a control program 2. The CF or SD interface circuit 11 is connected to the notebook or PDA for transmitting a control data produced from the control program in the notebook or PDA to the control chip and controlling the FM receiver 13 to receive a FM audio signal through a control signal produced from the control chip 12. The FM receiver 13 will transmit the received FM audio signal to the audio controller 14 and also send a control signal to the audio controller 14 through controlling the control chip 12. The audio controller 14 is controlled by the control signal produced from the control chip 12 to process the FM audio signal transmitted from the FM receiver 13, transmit thereof to the audio amplification circuit 15 for amplifying the audio signal, and then re-transmit thereof to the audio jack 16.

The notebook or PDA firstly has to load the control program 2 of the present invention. Then, the notebook or PDA will start the control program 2 to make a connection to the CF or SD interface circuit 11 of the FM receiving 1 through an application program, a driver, and a CF or SD interface driver. And, through the application program, a control data of the notebook or PDA can be transmitted via the built connection to the control chip 12, so that the control chip 12 can control the sent FM audio signal. The control method includes a FM frequency control 21 and an audio control 22.

The FM frequency control 21 includes radio station presetting 211 and automatic search 212. The radio station presetting 211 is proceeded by the application program in the notebook or PDA to select a radio frequency and then by a 3-wire control interface to load the data into a FM control register. And, the automatic search 212 is proceeded by the application program in the notebook or PDA to select the automatic search firstly and then by the 3-wire control interface to load the radio frequency into the FM control register, read the frequency data in the FM control register for confirming if the frequency data is correct or not, and load a correct frequency data into the FM control register.

The audio control 22 includes a volume control 221 and a mute control 222. The control signal is an I²C control signal which has a data format of:

“START”+“Address byte”+“ACK”+“DATA”+“ACK”+“DATA”+“ACK”+“STOP”

wherein the “Address byte” has a value of “10001000”, “11000001” or “11000000”.

The volume control 221 is proceed by the application program to adjust a degree of the volume firstly and then by an I²C control interface to read the data in an audio control register. And, the mute control 222 is proceeded by the application program to select or lift the mute firstly and then by the I²C control interface to load the data into a volume control register.

The FM receiving module for the PDA/notebook according to the present invention, when being compared with the other prior arts, further includes the advantages as follows:

1. The present invention provides a FM receiving module for a PDA/notebook to increase other functions of the notebook or PDA and also develop a greater efficiency of the notebook or PDA.

2. The present invention provides a FM receiving module for a PDA/notebook which can make a connection to a PDA or a notebook through a CF or SD interface thereof and also can, through a control program, control the searching or memorizing of the FM frequency in the FM receiving module and the transmission of the audio signal.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A FM receiving module for a PDA (Personal Digital Assistant)/notebook, comprising:
a control program for producing a control data;
a control chip for producing a control signal;
a CF interface circuit for receiving said control data produced from said control program and transmitting said control data to said control chip;
a FM receiver for being controlled by said control chip to receive a FM audio signal;
an audio controller for being controlled by said control signal produced from said control chip to process said FM audio signal transmitted from said FM receiver; and
an audio amplification circuit for receiving said FM audio signal which is processed by said audio controller and transmitting said FM audio signal to an audio jack.

2. The FM receiving module for a PDA/notebook according to claim 1, wherein said control program comprises an application program, a driver, and a CF interface driver and controls a FM frequency or an audio signal.

3. The FM receiving module for a PDA/notebook according to claim 1, wherein said CF interface circuit may be a SD interface circuit.

4. The FM receiving module for a PDA/notebook according to claim 2, wherein said CF interface driver may be a SD interface driver.

5. The FM receiving module for a PDA/notebook according to claim 2, wherein said FM frequency control comprises radio station presetting and automatic search;
wherein said radio station presetting is proceeded by said application program to select a radio frequency firstly and then by a 3-wire control interface to load said data into a FM control register; and
said automatic search is proceeded by said application program to select said automatic search firstly and then by said 3-wire control interface to load said radio frequency into said FM control register, read said frequency data in said FM control register for confirming if said frequency data is correct or not, and load a correct frequency data into said FM control register.

6. The FM receiving module for a PDA/notebook according to claim 2, wherein said audio control comprises volume control and mute control;
wherein said volume control is proceeded by said application program to adjust a degree of said volume firstly and then by an I²C control interface to load said data into said audio control register; and
said mute control is proceeded by said application program to select or lift said mute firstly and then by said I²C control interface to load said data into a volume control register.

7. The FM receiving module for a PDA/notebook according to claim 6, wherein said I²C has a data format of:
“START”+“Address byte”+“A CK”+“DATA”+“ACK”+“DATA”+“ACK”+“STOP”

8. The FM receiving module for a PDA/notebook according to claim 7, wherein said “Address byte” has a vale of “10001000”, “11000001” or “11000000”
